(19) United States
(12) Patent Application Publication
(10) Pub. No.: US 2005/0226442 A1
(43) Pub. Date: Oct. 13, 2005

(54) Method and apparatus for achieving temporal volume control

(76) Inventors: Michael D. Landon, Idaho Falls, ID (US); Jean-Marc Porson, Atlanta, GA (US); Robert H. Powell, Idaho Falls, ID (US)

Correspondence Address: KIRTON AND MCCONKIE;1800 EAGLE GATE TOWER, 60 EAST SOUTH TEMPLE, P O BOX 45120, SALT LAKE CITY, UT, 84145-0120, US

(21) Appl. No.: 10/822,545

(22) Filed: Apr. 12, 2004

(51) Int. Cl. H03G 3/00; H03G 3/20

(52) U.S. Cl. 381/104; 381/107; 700/94; 381/57

(57) ABSTRACT

A method and apparatus for temporal volume control that predicts and compensates for variances in ambient noise levels over time.

### BACKGROUND

1. Field of the Invention

The present invention relates to a sound volume control device. More particularly, the present invention relates to a sound volume control device to vary the volume level of a sound production system to compensate for variances in ambient noise levels.

2. Background

A sound production system is often implemented to convey information in a public setting. Particularly, a sound production system may be employed in a grocery or other retail store or shopping mall for advertising as well as general announcement purposes. Ambient noise in such a setting may muddle or render unintelligible and/or imperceptible the information thus conveyed. A customer's ability to effectively receive and process such information is thus dependent on the output level of the sound system relative to the level of ambient noise. Maintaining the sound system volume level a few decibels (dB) greater than the ambient noise level is thus paramount to effective communication of information to an intended audience.

One of the most commonly used approaches for overcoming ambient noise is to provide means for manually adjusting the volume level produced by the sound production system. Manual volume control, however, is generally not preferred as a primary means of controlling sound system output as it requires substantial time and effort while failing to ensure accurate control. Indeed, manual volume control is inherently inaccurate as it relies on subjectively perceived variances in ambient noise levels as well as subjectively applied modifications to the volume level to compensate for such variances.

Automatic means for dynamically varying an audio output level relative to an ambient noise level are also known. U.S. Pat. No. 4,553,257, for example, teaches an automatic sound volume control device for use in a device such as a radio or tape player used in a high ambient noise environment. Such systems, however, generally require complex circuitry to dynamically detect and adjust an audio output level relative to a constantly changing level of ambient noise. In addition, most such systems are integral to the sound production system itself and thus incapable of implementation after market.

Accordingly, what is needed is an apparatus for temporal volume control capable of quick and easy implementation in connection with new and existing sound systems. Also what is needed is a simple and inexpensive apparatus for temporal volume control that may effectively overcome variances in ambient noise levels over time.

### SUMMARY

The present invention comprises a method and apparatus for temporal volume control that predicts and compensates for variances in ambient noise levels over time.

Specifically, certain embodiments of the present invention comprise means for manually or automatically obtaining and/or recording ambient noise values over time to create a temporal ambient noise map that may be used to predict future ambient noise values. According to one embodiment, an ambient noise monitoring device iteratively records an ambient noise value corresponding to a time value over, for example, a twenty-four hour period of time. The monitoring device may then average the ambient noise values obtained for select time values and correlate an average ambient noise value to each time value, thus creating a temporal ambient noise map.

An audio output device may receive information from the temporal ambient noise map and use such information to maintain an audio volume level relatively greater than the average ambient noise values recorded on the map. In this manner, the audio output device may respond to predicted ambient noise levels such that information broadcast therefrom may be clearly perceived by an intended audience without unduly interfering with the audience's right to quiet enjoyment. In addition, the present invention allows for manual control of the audio output volume to compensate for unanticipated inconsistencies between a predicted and actual ambient noise level.

### BRIEF DESCRIPTION OF THE DRAWINGS

In order that the manner in which the above-recited and other advantages and features of the invention are obtained, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings in which:

FIG. 1 illustrates a representative system that provides a suitable operating environment for use of the present invention;

FIG. 2 is a block diagram of an apparatus capable of achieving temporal volume control in accordance with certain embodiments of the present invention;

FIG. 3 is a diagram comparing a temporal ambient noise map with audio output volume level in accordance with certain embodiments of the present invention; and

FIG. 4 is a flow chart detailing a method of achieving temporal volume control in accordance with certain embodiments of the present invention.

### DETAILED DESCRIPTION OF THE PREFERRED EMBODIMENTS

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

As used in this specification, the term “temporal volume control” refers to controlled variations in an audio output volume level over time. The term “ambient noise” refers to any sound or combination of sounds that interferes with the perceived clarity of sound produced by an audio output device in accordance with the present invention.

The following disclosure of the present invention is grouped into two subheadings, namely “Exemplary Operating Environment” and “Temporal Volume Control.” The utilization of the subheadings is for convenience of the reader only and is not to be construed as limiting in any sense.

### Exemplary Operating Environment

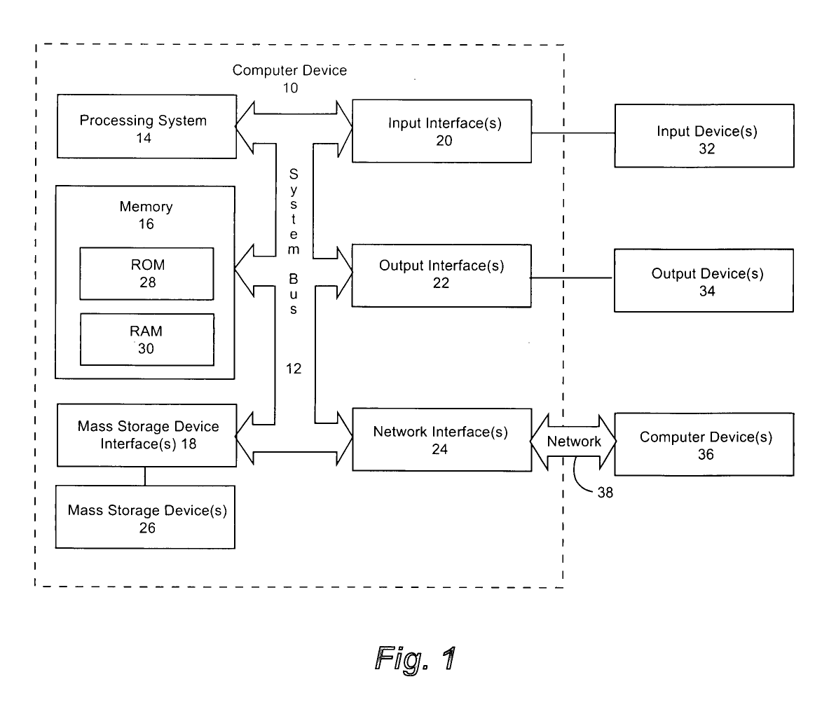

FIG. 1 and the corresponding discussion are intended to provide a general description of a suitable operating environment in which the invention may be implemented. One skilled in the art will appreciate that the invention may be practiced by one or more computing devices and in a variety of system configurations, including in a networked configuration.

Embodiments of the present invention embrace one or more computer readable media, wherein each medium may be configured to include or includes thereon data or computer executable instructions for manipulating data. The computer executable instructions include data structures, objects, programs, routines, or other program modules that may be accessed by a processing system, such as one associated with a general-purpose computer capable of performing various different functions or one associated with a special-purpose computer capable of performing a limited number of functions. Computer executable instructions cause the processing system to perform a particular function or group of functions and are examples of program code means for implementing steps for methods disclosed herein. Furthermore, a particular sequence of the executable instructions provides an example of corresponding acts that may be used to implement such steps. Examples of computer readable media include random-access memory (“RAM”), read-only memory (“ROM”), programmable read-only memory (“PROM”), erasable programmable read-only memory (“EPROM”), electrically erasable programmable read-only memory (“EEPROM”), compact disk read-only memory (“CD-ROM”), or any other device or component that is capable of providing data or executable instructions that may be accessed by a processing system.

With reference to FIG. 1, a representative system for implementing the invention includes computer device 10, which may be a general-purpose or special-purpose computer. For example, computer device 10 may be a personal computer, a notebook computer, a personal digital assistant (“PDA”) or other hand-held device, a workstation, a minicomputer, a mainframe, a supercomputer, a multi-processor system, a network computer, a processor-based consumer electronic device, or the like.

Computer device 10 includes system bus 12, which may be configured to connect various components thereof and enables data to be exchanged between two or more components. System bus 12 may include one of a variety of bus structures including a memory bus or memory controller, a peripheral bus, or a local bus that uses any of a variety of bus architectures. Typical components connected by system bus 12 include processing system 14 and memory 16. Other components may include one or more mass storage device interfaces 18, input interfaces 20, output interfaces 22, and/or network interfaces 24, each of which will be discussed below.

Processing system 14 includes one or more processors, such as a central processor and optionally one or more other processors designed to perform a particular function or task. It is typically processing system 14 that executes the instructions provided on computer readable media, such as on memory 16, a magnetic hard disk, a removable magnetic disk, a magnetic cassette, an optical disk, or from a communication connection, which may also be viewed as a computer readable medium.

Memory 16 includes one or more computer readable media that may be configured to include or includes thereon data or instructions for manipulating data, and may be accessed by processing system 14 through system bus 12. Memory 16 may include, for example, ROM 28, used to permanently store information, and/or RAM 30, used to temporarily store information. ROM 28 may include a basic input/output system (“BIOS”) having one or more routines that are used to establish communication. Such as during start-up of computer device 10. RAM 30 may include one or more program modules, such as one or more operating systems, application programs, and/or program data.

One or more mass storage device interfaces 18 may be used to connect one or more mass storage devices 26 to system bus 12. The mass storage devices 26 may be incorporated into or may be peripheral to computer device 10 and allow computer device 10 to retain large amounts of data. Optionally, one or more of the mass storage devices 26 may be removable from computer device 10. Examples of mass storage devices include hard disk drives, magnetic disk drives, tape drives and optical disk drives. A mass storage device 26 may read from and/or write to a magnetic hard disk, a removable magnetic disk, a magnetic cassette, an optical disk, or another computer readable medium. Mass storage devices 26 and their corresponding computer readable media provide nonvolatile storage of data and/or executable instructions that may include one or more program modules such as an operating system, one or more application programs, other program modules, or program data. Such executable instructions are examples of program code means for implementing steps for methods disclosed herein.

One or more input interfaces 20 may be employed to enable a user to enter data and/or instructions to computer device 10 through one or more corresponding input devices 32. Examples of such input devices include a keyboard and alternate input devices, such as a mouse, trackball, light pen, stylus, or other pointing device, a microphone, a joystick, a game pad, a satellite dish, a scanner, a camcorder, a digital camera, and the like. Similarly, examples of input interfaces 20 that may be used to connect the input devices 32 to the system bus 12 include a serial port, a parallel port, a game port, a universal serial bus (“USB”), a firewire (IEEE 1394), or another interface.

One or more output interfaces 22 may be employed to connect one or more corresponding output devices 34 to system bus 12. Examples of output devices include a monitor or display screen, a speaker, a printer, and the like. A particular output device 34 may be integrated with or peripheral to computer device 10. Examples of output interfaces include a video adapter, an audio adapter, a parallel port, and the like.

One or more network interfaces 24 enable computer device 10 to exchange information with one or more other local or remote computer devices, illustrated as computer devices 36, via a network 38 that may include hardwired and/or wireless links. Examples of network interfaces include a network adapter for connection to a local area network (“LAN”) or a modem, wireless link, or other adapter for connection to a wide area network (“WAN”), such as the Internet. The network interface 24 may be incorporated with or peripheral to computer device 10. In a networked system, accessible program modules or portions thereof may be stored in a remote memory storage device. Furthermore, in a networked system computer device 10 may participate in a distributed computing environment, where functions or tasks are performed by a plurality of networked computer devices.

### Temporal Volume Control

An apparatus for achieving temporal volume control in accordance with the present invention may comprise an audio output component 130 for producing an audio output volume level 132 greater than a predicted level of ambient noise. A level of ambient noise may be predicted based on ambient noise values obtained and/or recorded over time. Such ambient noise values may be obtained and/or recorded by any means known to those in the art, including but not limited to manually recording values based on subjectively perceived levels of ambient noise. Alternatively, certain embodiments of the present invention may comprise a monitoring component 110 capable of objectively obtaining and recording ambient noise values.

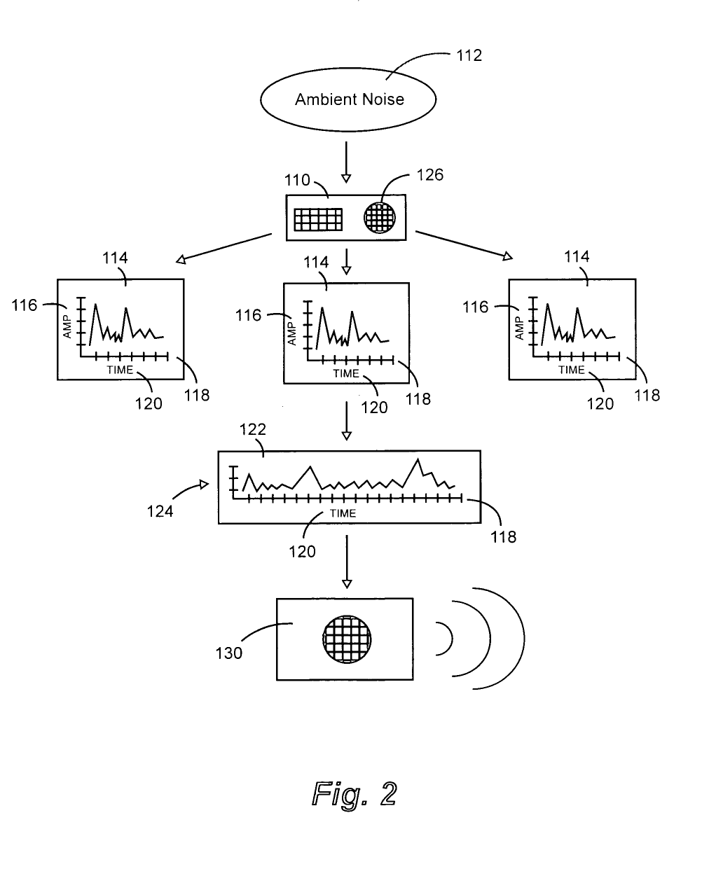

Referring now to FIG. 2, the monitoring component 110 and audio output component 130 may be integral with or independent of one another. For example, as discussed above with reference to an exemplary embodiment of the present invention, the monitoring component 110 and audio output component 130 may each be implemented in a single computer device 10, or at least one component 110 and 130 may reside separately on one or more peripheral computer devices 10 capable of hardwired or remote communication with the primary computer device 10.

A monitoring component 110 may comprise a microphone 126 or other input device 32 known to those in the art capable of detecting and/or transmitting ambient noise levels 112. Such ambient noise levels 112 may be recorded by a memory element 128 integral to or independent of the monitoring component 110. A memory element 128 may comprise, for example, computer readable media or any other means of recording ambient noise levels 112 known to those in the art. Preferably, a memory element 128 in accordance with the present invention is capable of recording ambient noise levels 112 over time.

A processing element 134 integral to or independent of the monitoring component 110 and/or the audio output component 130 may then process the ambient noise levels 112. A processing element 134 may assign an ambient noise value 116 and a time value 118 to ambient noise values 112 over a specific time period 120. A time period 120 may comprise, for example, twenty-four hours. Ambient noise values 116 corresponding to a specific time value 118 for more than one time period 120 may then be averaged to obtain an average ambient noise value 122 corresponding to each time value 118. A temporal noise map 124 may then correlate average ambient noise values 122 with specific time values 118 over a time period 120.

The processed information thus derived, and particularly the temporal noise map 124, may be then transmitted to and received by an audio output component 130. An audio output component 130 in accordance with certain embodiments of the present invention may comprise a loudspeaker or other sound production system or output device 34 known to those in the art capable of communicating with the processing element 134 and receiving the temporal ambient noise map 124.

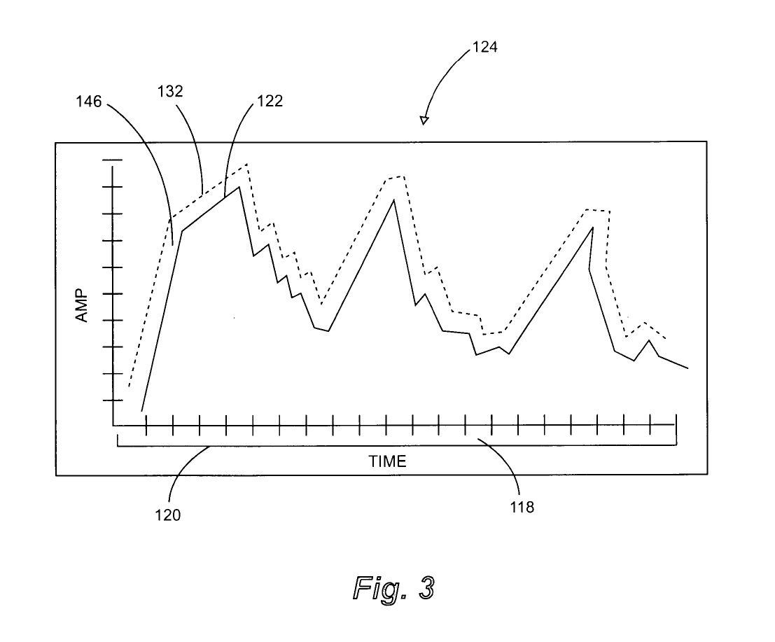

Referring now to FIG. 3, the audio output component 130 may adjust an audio output volume level 132 to substantially mirror the temporal ambient noise map 124. Preferably, the audio output component 130 maintains the audio output volume level 132 at a level discernibly greater than any particular average ambient noise value 122 corresponding to a repeatable time value 118 such that the audio output produced at a present such time value 118 may be perceived intelligibly above a predicted level of ambient noise 112. According to certain embodiments of the present invention, the ratio of audio output volume levels 132 to predicted ambient noise values 122 is constant. Alternatively, an audio output volume level 132 may be maintained a constant number of decibels greater than the predicted ambient noise values 122. In either case, the result is to render the audio output perceptible and intelligible over predicted variances in ambient noise levels 112. The difference between the predicted level of ambient noise 122 and an audio output volume level 132 obtained in accordance with the present invention may be referred to as an amplitude variance constant 140.

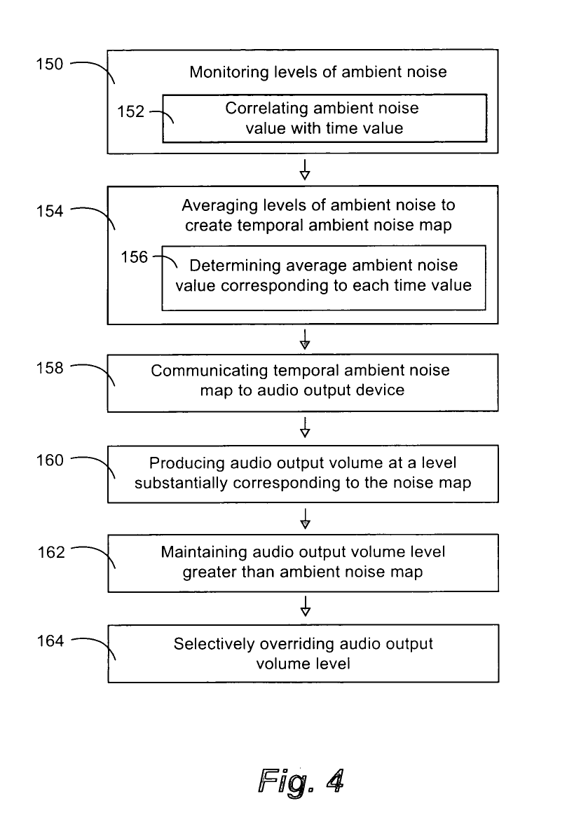

Referring now to FIG. 4, a method for achieving temporal volume control in accordance with the present invention may comprise first monitoring levels of ambient noise in a specific location over time 150. A next step may comprise correlating ambient noise values with specific repeatable time values over a specified time period 152. A plurality of ambient noise levels may then be averaged to create a temporal ambient noise map 154. Specifically, a plurality of ambient noise levels corresponding to each repeatable time value may be averaged and recorded such that a temporal ambient noise map thus created reflects a predicted ambient noise level per time value 156.

Next, a method in accordance with the present invention may comprise communicating information corresponding to the temporal ambient noise map to an audio output device 158 such that the audio output device may produce an audio output volume level substantially corresponding to the temporal ambient noise map 160. In this manner, an audio output volume level may be selectively varied to overcome predicted fluctuations in a level of ambient noise over time. More particularly, the audio output volume level may be maintained at a level greater than the predicted ambient noise level such that the audio output may be intelligibly perceived by the public 162. The audio output volume level thus produced may be optionally disabled, enhanced, or reduced by providing a manual volume override mechanism 164.

1. A temporal volume control device comprising:
an audio output component for receiving information corresponding to a temporal ambient noise map and producing an audio volume level substantially corresponding to and greater than said temporal ambient noise map, said temporal ambient noise map comprising at least one ambient noise value corresponding to a time value for at least one period of time.

2. The temporal volume control device of claim 1, wherein said audio output component utilizes said temporal ambient noise map to predict future ambient noise values.

3. The temporal volume control device of claim 1, wherein a difference between said audio volume level and said temporal ambient noise map is constant over time.

4. The temporal volume control device of claim 1, wherein said audio output component further comprises a manual volume control to selectively override said audio volume level.

5. The temporal volume control device of claim 1, wherein said at least one period of time comprises twenty-four hours.

6. The temporal volume control device of claim 1, further comprising an ambient noise monitoring component for iteratively recording at least one ambient noise value corresponding to a time value for at least one period of time to create said temporal ambient noise map.

7. The temporal volume control device of claim 6, wherein said ambient noise monitoring component operates independently of said audio output component.

8. The temporal volume control device of claim 6, wherein said ambient noise monitoring component is integral to said audio output component.

9. The temporal volume control device of claim 6, wherein said ambient noise monitoring component further averages said at least one ambient noise value corresponding to said time value over said at least one period of time to obtain an average ambient noise value corresponding to said time value.

10. The temporal volume control device of claim 9, wherein said temporal ambient noise map comprises said average ambient noise values corresponding to said time values over said period of time.

11. A method for controlling audio output volume, said method comprising:
monitoring levels of ambient noise over at least one period of time;
averaging said levels of ambient noise to create a temporal ambient noise map;
communicating said temporal ambient noise map to an audio output device, said audio output device capable of automatically adjusting an audio output volume level to substantially correspond to said temporal ambient noise map; and
producing, via said audio output device, audio information according to said audio output volume level.

12. The method of claim 11, wherein said monitoring further comprises correlating at least one ambient noise value with at least one time value over said at least one period of time.

13. The method of claim 12, wherein said averaging further comprises determining an average ambient noise value corresponding to said at least one time value over said at least one period of time.

14. The method of claim 11, further comprising maintaining said audio output volume level at a level greater than levels corresponding to said temporal ambient noise map.

15. The method of claim 14, wherein a difference between said audio output volume level and said levels corresponding to said temporal ambient noise map is constant over time.

16. The method of claim 11, further comprising selectively overriding, via a manual volume control, said audio output volume level.

17. The method of claim 11, wherein said at least one period of time comprises twenty-four hours.

18. A computer program product for implementing within a computer system a method for controlling audio output volume, said computer program product comprising:
a computer readable medium for providing computer program code means utilized to implement the method, wherein the computer program code means is comprised of executable code for implementing the steps for:
producing audio output substantially corresponding to and greater than a temporal ambient noise map, wherein said temporal ambient noise map comprises at least one average ambient noise value corresponding to a time value for at least one period of time.

19. The computer program product of claim 18, wherein said computer program code further comprises executable code for implementing the steps for:
monitoring levels of ambient noise over at least one period of time; and
averaging said levels of ambient noise to create said temporal ambient noise map.
